(19) United States
(12) Patent Application Publication
(10) Pub. No.: US 2006/0045290 A1
(43) Pub. Date: Mar. 2, 2006

(54) Mechanical roller controller

(76) Inventors: Shih-Wei Lin, Pan Chiao City (TW); Zhi-Feng Chen, Pan Chiao City (TW); Wei-Tai Lin, Taoyuan Hsien (TW)

Correspondence Address: RABIN & BERDO, P.C., Suite 500, 1101 14 Street, N.W., Washington, DC, 20005, US

(21) Appl. No.: 11/032,048

(22) Filed: Jan. 11, 2005

(30) Foreign Application Priority Data
Aug. 27, 2004 (TW) 93213677

(51) Int. Cl. H03G 3/00; A63C 17/00; A63C 19/10

(52) U.S. Cl. 381/109; 381/107; 280/11.19; 280/843; 472/89

(57) ABSTRACT

A mechanical roller controller is installed on a substrate. Two switches, which are secured on the substrate, send digital signals when they are pressed. A base is disposed on the substrate. Two pedals are installed on the base and near the two switches, and each pedal is pivotally connected with the base. A roller, having two gears, is mounted on the base. A first gear is positioned within reach of the two pedals. A second gear is designed for users to take control by their fingers. When the second gear rotates, the first gear rotates simultaneously. Two pedals, driven by the first gear, move along opposite directions. One of the two pedals moves downward to press the switch and returns to its original position by being pushed back by the switch.

### RELATED APPLICATIONS

The present application is based on, and claims priority from, Taiwan Application Serial Number 93213677, filed Aug. 27, 2004, the disclosure of which is hereby incorporated by reference herein in its entirety.

### BACKGROUND

1. Field of Invention

The present invention relates to a mechanical roller controller. More particularly, the present invention relates to a mechanical roller volume controller for increasing or decreasing audio volume.

2. Description of Related Art

The most common way to control audio volume of a multimedia device, such as a TV or a Notebook PC, is to provide two buttons (one for increasing the audio volume, the other for decreasing the audio volume) on the outer housing of the multimedia device for manual control. A switch is positioned under each of the two buttons that outputs a signal either to increase or decrease the audio volume when a button is pressed.

The above design for increasing or decreasing the audio volume may need consecutive finger presses (or touches) of a user. Fatigue failures on switches are unavoidable. Furthermore, improper usage (such as applying intense force when pressing a button) may damage the switches and shorten their life cycle.

### SUMMARY

It is therefore an objective of the present invention to provide a mechanical roller controller so as to overcome the shortcomings of conventional audio controllers.

In accordance with the foregoing and other objectives of the present invention, a mechanical roller controller is installed on a substrate. Two switches, which are secured on the substrate, send digital signals when they are pressed. A base is disposed on the substrate. Two pedals are installed on the base and near the two switches, and each pedal is pivotally connected with the base. A roller, having two gears, is mounted on the base. A first gear is positioned within reach of the two pedals. A second gear is designed for users to take control by their fingers. When the second gear rotates, the first gear rotates simultaneously. Two pedals, driven by the first gear, move in opposite directions. One of the two pedals moves downward to press the switch and returns to its original position by being pushed back by the switch.

Thus, the mechanical roller controller can be applied to control audio volume. The mechanical roller controller can be designed smaller and cheaper in comparison with optical roller controllers. Because the switch is pressed by a uniform force directly provided by the roller gear, rather than directly by a user's fingers, the life cycle of the switch can be thus extended.

It is to be understood that both the foregoing general description and the following detailed description are by examples and are intended to provide further explanation of the invention as claimed.

### BRIEF DESCRIPTION OF THE DRAWINGS

The accompanying drawings are included to provide a further understanding of the invention and are incorporated in and constitute a part of this specification. The drawings illustrate embodiments of the invention and, together with the description, serve to explain the principles of the invention. In the drawings,

FIG. 1A illustrates a perspective view of a mechanical roller controller according to one preferred embodiment of this invention;

FIG. 1B illustrates a side view of a mechanical roller controller according to one preferred embodiment of this invention;

FIG. 2A illustrates a perspective view of a mechanical roller controller with an outer housing according to one preferred embodiment of this invention; and

FIG. 2B illustrates a side view of a mechanical roller controller with an outer housing according to one preferred embodiment of this invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

In order to overcome the shortcomings of conventional audio controllers, the present invention provides a mechanical roller controller. The roller controller includes two roller gears, of which one is for manual control and the other is to press switches. Because roller gears are secured on the same shaft, one roller gear is rotated by a user's finger while the other roller gear presses switches. By clockwise or counter-clockwise rotation of the roller gears, the switches are pressed successively to control audio volume.

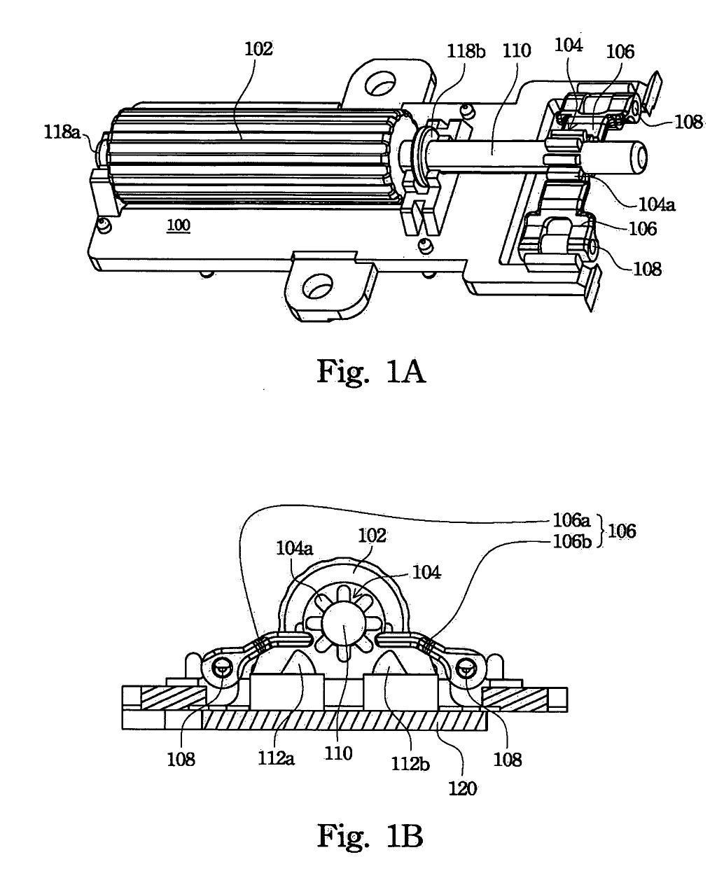

FIG. 1A illustrates a perspective view of a mechanical roller controller according to one preferred embodiment of this invention. Roller gears 102 and 104 are secured on a shaft 110, which is mounted on a base 100. The shaft 110 is mounted on the base 100 by means of shaft bearings 118a and 118b. The roller gear 102 should be large enough in size so that users can operate it with their fingers. When the roller gear 102 rotates, the roller gear 104 rotates simultaneously to drive two pedals 106.

FIG. 1B illustrates a side view of a mechanical roller controller according to one preferred embodiment of this invention. Two switches 112a and 112b are respectively installed on a substrate 120, such as a printed circuit board. The switches 112a and 112b include sensor switch, jiggle switch or micro switch. The switches 112a and 112b, when pressed, output digital signals to control audio volume. The base 100 is secured on the substrate 120. Two pedals 106a and 106b are respectively positioned corresponding to switches 112a and 112b. One end of the pedals 106a and 106b is pivotally connected with the base 100 by a joint 108, and the other end is respectively positioned above each of corresponding switches 112a and 112b. The roller gear 104 is positioned adjacent to both of the two pedals 106a and 106b so that the roller gear 104 can drive them.

The roller gear 104 drives the pedal 106 to press the switch 112 by means of its teeth 104a, and then the switch 112 outputs digital signals. One end of the pedal 106 is within reach of the teeth 104a and the other end is pivotally connected with the base 100 by the joint 108. When the roller gear 102, which is controlled by a user, rotates counter-clockwise, the roller gear 104 rotates counter-clockwise simultaneously. The pedal 106a, which is driven by the teeth 104a, rotates downwards while the pedal 106b, which is driven by the teeth 104a as well, rotates upwards. Thus, only the pedal 106a, which is driven by the teeth 104a, can rotate downwards to reach the switch 112a when the roller gear 104 rotates counter-clockwise. The switch 112a, which is pressed, outputs digital signals. In practice, the switch 112a should have the capability of returning to its original position before pressing so that a next tooth of the roller gear 104 can drive the pedal 106a to press the switch 112a again. If the roller gear 104 rotates counter-clockwise successively, the switch 112a outputs digital signals continuously to increase or decrease the audio volume.

When the roller gear 102, which is controlled by a user, rotates clockwise, the roller gear 104 rotates clockwise simultaneously. The pedal 106a, which is driven by the teeth 104a, rotates upwards while the pedal 106b, which is driven by the teeth 104a as well, rotates downwards. Thus, only pedal 106b, which is driven by the teeth 104a, can rotate downwards to reach the switch 112b when the roller gear 104 rotates clockwise. The switch 112b, which is pressed, outputs digital signals. In practice, the switch 112b should have the capability of returning to its original position before pressing so that a next tooth of the roller gear 104 can drive the pedal 106b to press the switch 112b again. If the roller gear 104 rotates clockwise successively, the switch 112b outputs digital signals continuously to increase or decrease the audio volume.

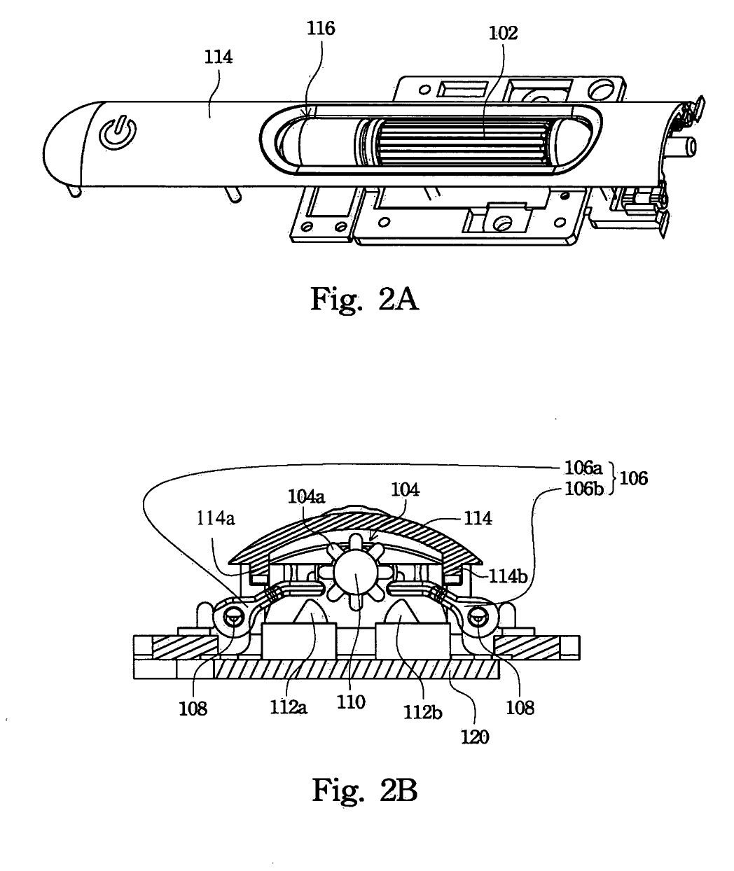

FIG. 2A illustrates a perspective view of a mechanical roller controller with an outer housing according to one preferred embodiment of this invention. An outer housing 114 includes an opening 116, corresponding to the roller gear 102, to expose the roller gear 102 for manual control by users.

FIG. 2B illustrates a side view of a mechanical roller controller with an outer housing according to one preferred embodiment of this invention. The outer housing 114 includes two positioning ribs 114a and 114b on the inner wall. The positioning ribs 114a and 114b block the pedals 106a and 106b when they are pushed back by the switch 112a and 112b to their original position before being pressed.

According to preferred embodiments of present invention, the mechanical roller controller can be applied to control audio volume. The mechanical roller controller can be designed smaller and cheaper in comparison with optical roller controllers. Because the switch is pressed by a uniform force directly provided by the roller gear, rather than directly by a user's fingers, the life cycle of the switch can be thus extended.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A mechanical roller controller, comprising:
a substrate;
two switches, mounted on said substrate, said switches outputting digital signals when being pressed;
a base, fixed on said substrate;
two pedals, one end of each said pedal being pivotally connected with said base, the other end of each said pedal being positioned above each said switch so as to press each said switch;
a shaft, mounted on said base;
a first roller gear, being secured on said shaft and positioned adjacent to both said pedals to drive said pedals; and
a second roller gear, being secured on said shaft for manual control to drive said first roller gear simultaneously, wherein said two pedals are respectively driven along opposite directions so that one of said switches is pressed by one of said pedals at one time, and after being pressed, each said switch returns to its original position before being pressed again so that a next tooth of said first roller gear can drive each said pedal for pressing each said switch again.

2. The mechanical roller controller of claim 1, further comprising an outer housing, positioned above said pedals, to block each said pedal when being pushed back by each said switch.

3. The mechanical roller controller of claim 2, wherein said outer housing includes an opening, corresponding to said second roller gear, to expose said second roller gear for manual control.

4. The mechanical roller controller of claim 1, wherein said switches include sensor switches, jiggle switches and micro switches.

5. A mechanical roller volume controller, comprising:
a substrate;
two switches, mounted on said substrate, said switches outputting digital signals to respectively increase or decrease an audio volume when pressed;
a base, fixed on said substrate;
two pedals, one end of each said pedal being pivotally connected with said base, the other end of each said pedal being positioned above each said switch so as to press each said switch;
a shaft, mounted on said base;
a first roller gear, being secured on said shaft and positioned adjacent to both said pedals to drive said pedals; and
a second roller gear, being secured on said shaft for manual control to drive said first roller gear simultaneously, wherein said two pedals are respectively driven along opposite directions so that one of said switches is pressed by one of said pedals at one time, and after being pressed, each said switch returns to its original position before being pressed again so that a next tooth of said first roller gear can drive each said pedal for pressing each said switch again.

6. The mechanical roller volume controller of claim 5, further comprising an outer housing, positioned above said pedals, to block each said pedal when being pushed back by each said switch.

7. The mechanical roller volume controller of claim 6, wherein said outer housing includes an opening, corresponding to said second roller gear, to expose said second roller gear for manual control.

8. The mechanical roller volume controller of claim 5, wherein said switches include sensor switches, jiggle switches and micro switches.
